(19) United States
(12) Patent Application Publication
(10) Pub. No.: US 2024/0274739 A1
(43) Pub. Date: Aug. 15, 2024

(54) PHOTOVOLTAIC STRING

(71) Applicant: COMMISSARIAT À L’ENERGIE ATOMIQUE ET AUX ENERGIES ALTERNATIVES, PARIS (FR)

(72) Inventor: Armand BETTINELLI, GRENOBLE CEDEX 9 (FR)

(21) Appl. No.: 18/569,516

(22) PCT Filed: May 24, 2022
(86) PCT No.: PCT/EP2022/064078

§ 371 Date: Dec. 12, 2023

(30) Foreign Application Priority Data
Jun. 14, 2021 (FR) FR2106249

(51) Int. Cl. H01L 31/05; H01L 31/02; H01L 31/0224

(52) U.S. Cl. CPC H01L 31/0516; H01L 31/0201; H01L 31/022433

(57) ABSTRACT

A photovoltaic string includes a first photovoltaic cell; a second photovoltaic cell; a first metal connector, the first photovoltaic cell being disposed between the second photovoltaic cell and the first metal connector, each of the first and second photovoltaic cells including a first face and a second face opposite to the first face, the first faces each including collection fingers extending parallel to each other, the first photovoltaic cell being interconnected to the second photovoltaic cell, the second face of the first photovoltaic cell partially covering the first face of the second photovoltaic cell, and first connection elements disposed on the first face of the first photovoltaic cell and extending beyond the first photovoltaic cell, up to the first metal connector, wherein the first connection elements electrically connect at least part of the collection fingers of the first face of the first photovoltaic cell to the first metal connector.

### TECHNICAL FIELD OF THE INVENTION

The technical field of the invention is that of photovoltaic cell strings and in particular the connection of said strings to a metal connector.

### TECHNOLOGICAL BACKGROUND OF THE INVENTION

A photovoltaic string is formed by the series interconnection of a plurality of photovoltaic cells forming a cell string, each end of the string being connected to a metal connector. When so formed, the string can be connected within an electrical grid and provide electric energy to the electrical grid. The method commonly used to form strings is to weld or bond tapes or wires to collection fingers on the front face of a first cell and to collection fingers on the rear face of an adjacent second cell. The first and second cells are separated by a few millimetres, approximately 3 mm, so that the tape or wire can change plane and pass from the front face of the first cell to the rear face of the second cell. The spacing between the cells increases the surface area of the string thus formed.

There is a cell interconnection technique called “shingle” which does not use tapes or electrical wires and makes it possible to increase surface area of the photovoltaic string AA. The shingled interconnection technique is illustrated in FIG. 1 and is, for example, described in the paper [“Materials challenge for shingled cells interconnection”, G. Beaucarne, Energy Procedia 98, pp. 115-124, 2016]. The cells C forming the string AA are superimposed on each other, with a lower cell partially covered with an adjacent upper cell C, in the same way as cells cover a roof. Two adjacent cells AA are interconnected in a coverage zone along one edge by welding or bonding. The interconnected shingle string AA thus eliminates separation between the cells, providing a continuous active surface area over the entire string. Current interconnection technologies, especially those implementing bonding using an electrically conductive adhesive, have made it possible to achieve reliable interconnection between cells C while reducing the coverage surface areas between two consecutive cells. Interconnections between cells C are then able to withstand seasonal thermal expansion stresses.

For the string AA to be electrically connected to an electrical grid, it comprises metal connectors M interconnected at each end cell C. The connectors M can be interconnected in a shingled manner with the end cells C, that is by partially covering one face of each end cell C. Electrical and mechanical interconnection between the end cells C and the connectors M can be achieved by welding or bonding. However, they do not offer the same level of robustness as between two consecutive cells C, especially when bonding is carried out using an electrically conductive adhesive. It is thereby necessary to transfer each connector M onto a large surface area of each end cell C, reducing the active surface area thereof, or else to implement a large amount of electrically conductive adhesive, representing a significant proportion of the manufacturing cost of said string.

There is therefore a need to improve reliability of the connection of metal connectors to a photovoltaic string in which the photovoltaic cells are interconnected in shingles.

### SUMMARY OF THE INVENTION

The photovoltaic string according to the invention offers improved reliability in comparison with a string according to prior art because it reduces thermal deformation of photovoltaic cells directly connected to a metal connector (bimetal effect).

For this, the invention relates to a photovoltaic string comprising:
a first photovoltaic cell;
a second photovoltaic cell; and
a first metal connector;
   the first photovoltaic cell being disposed between the second photovoltaic cell and the first metal connector, each of the first and second photovoltaic cells comprising a first face and a second face opposite to the first face, said first faces each comprising a plurality of collection fingers extending parallel to each other, the first photovoltaic cell being interconnected to the second photovoltaic cell, the second face of the first photovoltaic cell partially covering the first face of the second photovoltaic cell, the photovoltaic string being remarkable in that it comprises a plurality of first connection elements, said first connection elements being disposed on the first face of the first photovoltaic cell and extending beyond the first photovoltaic cell, up to the first metal connector, and in that the first connection elements electrically connect at least part of the collection fingers of the first face of the first photovoltaic cell to the first metal connector.

Further to the characteristics just discussed in the preceding paragraph, the photovoltaic string according to one aspect of the invention may have one or more complementary characteristics from among the following, considered individually or according to any technically possible combinations:
the first metal connector is distant from the first photovoltaic cell, preferably by of at least 1 mm;
the first photovoltaic cell comprises a first edge vertically above the first face of the second photovoltaic cell; the collection fingers extend parallel to the first edge; and each connection element extends perpendicular to the collection fingers;
each first connection element comprises an end disposed within 5 mm of the first edge;
the photovoltaic string comprises a second plurality of connection elements, the second connection elements electrically interconnecting at least some of the collection fingers of the first face of the second photovoltaic cell, the number of second connection elements being greater than or equal to the number of first connection elements;
the width of each first connection element is greater than or equal to the width of each second connection element;
the photovoltaic string comprises spacing means configured to ensure constant pitch between the first connection elements;
the spacing means comprise a plurality of conductive wires; each conductive wire is integral with the first connection elements and extends perpendicular to the first connection elements so that the plurality of conductive wires and the first connection elements form a grid;
the spacing means comprise a support film integral with the first connection elements;
the photovoltaic string comprises a third photovoltaic cell and a second metal connector, the third photovoltaic cell being disposed between the second photovoltaic cell and the second metal connector, the third photovoltaic cell comprising a first face and a second face opposite to the first face, a plurality of third connection elements electrically connecting the second metal connector to the second face of the third photovoltaic cell.

Another aspect of the invention relates to a method for manufacturing a photovoltaic string comprising the following steps of:
providing a first photovoltaic cell, a second photovoltaic cell and a first metal connector, each of the first and second photovoltaic cells comprising a first face and a second face opposite to the first face, said first faces each comprising a plurality of collection fingers extending parallel to each other, those of the first cell being parallel to the edge, the first photovoltaic cell being disposed between the second photovoltaic cell and the first metal connector;
interconnecting the first photovoltaic cell to the second photovoltaic cell, the second face of the first photovoltaic cell partially covering the first face of the second photovoltaic cell,
electrically connecting at least part of the collection fingers of the first face of the first photovoltaic cell to the first metal connector by means of first connection elements, said first connection elements being disposed on the first face of the first photovoltaic cell and extending beyond the first photovoltaic cell, up to the first metal connector.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 schematically represents one embodiment of a photovoltaic string according to prior art, interconnected as a shingle.

FIG. 2, FIG. 4, FIG. 5, FIG. 6a, FIG. 7, FIG. 8, FIG. 9, FIG. 10, FIG. 11 schematically represent several embodiments of a photovoltaic string according to the invention.

FIG. 3 schematically represents one example of a photovoltaic cell.

FIG. 6b schematically represents one example of connection between a first connection element and a photovoltaic cell.

FIG. 12 schematically represents an implementation mode of a method for manufacturing according to the invention.

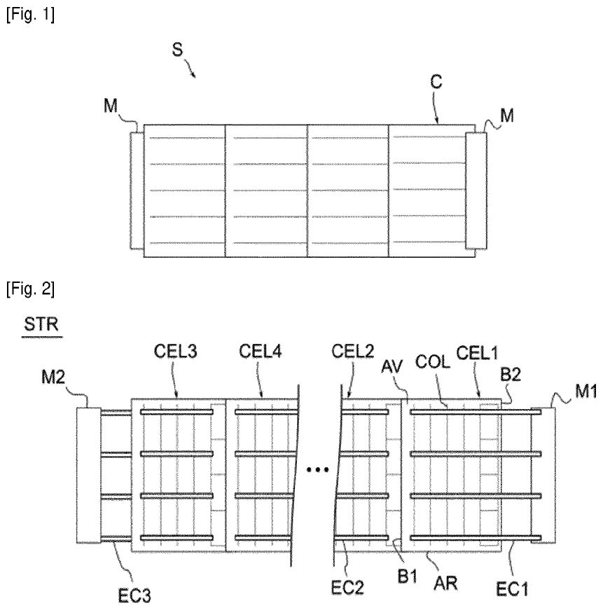

The figures are set forth by way of indicating and in no way limiting purposes of the invention. Unless otherwise specified, a same element appearing in different figures has a single reference. A reference sign ‘Xm-p’, where ‘m’ and ‘p’ are natural numbers, refers to all the reference signs between m and p. For example, “CEL1-4” refers to “CEL1”, “CEL2”, “CEL3” and “CEL4”.

### DETAILED DESCRIPTION

The invention relates to a photovoltaic string offering improved reliability, especially when the string comprises a plurality of shingle connected photovoltaic cells. Different embodiments of the photovoltaic string are illustrated in FIG. 2, FIG. 4 to FIG. 6a and FIG. 7 to FIG. 11.

For this, in common with FIG. 2, FIG. 4 to FIG. 6a FIG. 7 to FIG. 11, the photovoltaic string STR, which will also be referred to simply as a string, comprises:
a first photovoltaic cell CEL1;
a second photovoltaic cell CEL2; and
a first metal connector M1.

The first photovoltaic cell CEL1 is disposed between the second photovoltaic cell CEL2 and the first metal connector M1. Each of the first and second photovoltaic cells CEL1, CEL2 comprises a first face AV and a second face AR, opposite to the first face AV. Said first faces AV each comprise a plurality of collection fingers COL extending parallel to each other. The first photovoltaic cell CEL1 is interconnected to the second photovoltaic cell CEL2, the second face AR of the first photovoltaic cell CEL1 partially covering the first face AV of the second photovoltaic cell CEL2.

The string STR is remarkable in that it comprises a plurality of first connection elements EC1 disposed on the first face AV of the first photovoltaic cell CEL1 and extending beyond the first photovoltaic cell CEL1, up to the first metal connector M1. The string STR is also remarkable in that the first connection elements EC1 electrically connect at least part of the collection fingers COL of the first face AV of the first photovoltaic cell EC1 to the first metal connector M1.

The first and second photovoltaic cells CEL1, CEL2 of the string STR are interconnected in a shingle configuration. The interconnection of the cells CEL1, CEL2 as a shingle makes it possible to minimise surface area occupied by the string STR while maximising the useful surface area of said string STR. By useful surface area or active surface area, it is meant the surface area of the string STR to be exposed to incident radiation in order to generate electric current.

Unlike a shingled interconnected string according to prior art, the connection between the first connector M1 and the first cell CEL1 of the string STR is not made as a shingle. Namely, the first cell CEL1 is not directly and rigidly connected to the first connector M1. Thus, deformation of the first connector M1, relative to the first cell CEL1, does not cause deformation of the first cell CEL1. For example, thermal expansion of the first connector M1 does not cause stress or deformation of the first cell CEL1 by bimetal effect. The first connection elements EC1 provide electrical connection between the collection fingers COL, designed to collect the currents generated by the string STR, with the first connector M1. Removing the bimetal effect between the first connector M1 and the first cell CEL1 also makes it possible to implement thinner photovoltaic cells, for example with a thickness of 100 μm.

The string STR according to the invention also offers other advantages. For example, the reduction in the amount of raw material implemented to electrically connect the first connector M1 to the first photovoltaic cell CEL1. For example, when the interconnection between the cells CEL1, CEL2 is implemented by bonding, the amount of adhesive implemented only represents about 2 mg. On the other hand, bonding a connector to a cell of a string according to prior art requires a higher amount of adhesive, of approximately 10 mg. The first connection elements EC1 can be connected to the first cell CEL1 without the addition of material, eliminating the amount of adhesive implemented according to prior art. For example, they can be directly welded to the collection fingers COL by means of a fusible alloy covering them.

According to the embodiment of FIG. 2, the string according to the invention is an assembly of interconnected shingle cells themselves connected to metal connectors. In addition to the first and second cells CEL1, CLE2, the string STR can of course include a third photovoltaic cell CEL3. In this case, the first and third cells CEL1, CEL3 can thereby form the ends of the string STR. In other words, all the cells in the string STR can be disposed between these end cells CEL1, CEL3. The string STR may also comprise at least a fourth photovoltaic cell CEL4, disposed between the end cells CEL1, CEL3.

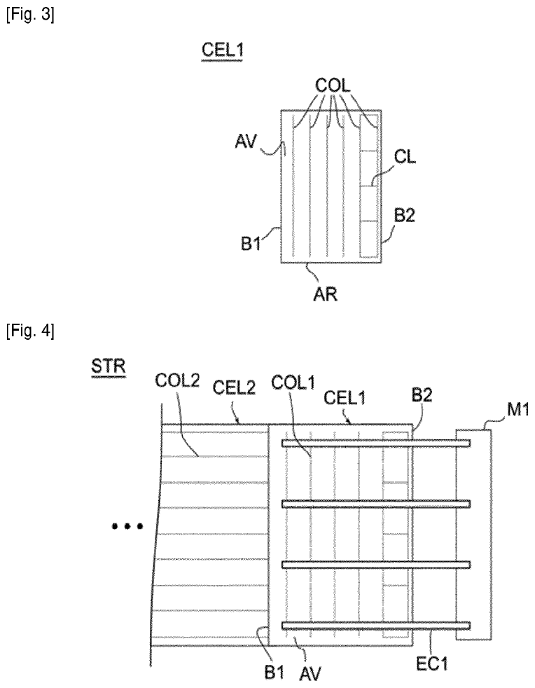

FIG. 3 schematically represents one embodiment of the first cell CEL1 before being connected within said string. The cells CEL1-4 may be different. However, it is advantageous, especially for manufacturing reasons, for the cells CEL1-4 of the string STR to be identical. In this case, the characteristics described with reference to FIG. 3 can also be transposed to the other cells CEL2-4 of the string STR.

The first cell CEL1, and advantageously each cell CEL1-4, may have a rectangular shape or a pseudo-rectangular shape. By pseudo-rectangular, it is meant that two of the four corners of a rectangle are truncated. The first cell CEL1 can have, for example, a dimension of 156 mm by 156 mm or else a subdivision of these dimensions, for example 156 mm by 78 mm, 156 mm by 52 mm, 156 mm by 31.2 mm or even 156 mm by 26 mm. The cell comprises a first edge B1 and advantageously a second edge B2 opposite to the first edge B1. The first and second edges B1, B2 are preferably the long edges of the first cell CEL1.

The first cell CEL1, and advantageously each cell CEL1-4, also comprises a first face AV and a second face AR, opposite to the first face AV. The first face AV may be the front face of the cell, that is the face to be exposed to incident solar radiation in order to produce electric energy. The second face AR may also be intended to be exposed to incident solar radiation in order to produce electric energy. The first face AV of the first cell CEL1 is visible in [FIG. 3] while its second face AR is hidden.

The photovoltaic cell of the string STR is advantageously made from a semiconductor stack so that, once exposed to incident radiation, it can generate electric current. Semiconductor stacks can be with silicon homojunction or silicon heterojunction. The invention is particularly relevant in the latter case, as heterojunction semiconductor stacks generally have a lower thermal budget than homojunction semiconductor stacks.

Indeed, technical limitations for manufacturing a string from heterojunction stacks, implied by the reduced thermal budget, also tend to reduce mechanical reliability of said strings. According to prior art, a metal connector is connected to a cell using metallised parts, which can also be referred as metallisations. This is, for example, a busbar extending along one edge of the cell and to which the metal connector is bonded or welded. However, the adhesion of the metallisations to the surface of the stack may be limited. This is because the metallisations can be produced using an electrically conductive ink that may contain an epoxy- or acrylate-based resin. This type of resin shows limited adhesion to the surface of the stack when cross-linked at low temperature, for example about 200° C. Thus, expansion of the metal connector connected according to prior art to the stack, that is directly to a metallisation, may cause said metallisation to pull off.

The invention provides a solution to this reduction in reliability, making it possible to produce a string using cells with a reduced thermal budget, but with a level of reliability close to that of strings produced using cells with a high thermal budget. For this, the first metal connector M1 is not connected directly, that is rigidly, to the metallisations of the first cell CEL1. This is an electrical connection which is made via the first connection elements EC1. Thus, expansion of the first metal connector does not cause the metallisations to pull off.

The first face AV of the first cell CEL1, and advantageously each cell CEL1-4, has a plurality of collection fingers COL, as illustrated by FIG. 3, configured to collect electrical currents generated by said cell. The collection fingers COL extend parallel to one another, for example, from one edge of the first cell CEL1 to the other. Advantageously, the collection fingers COL can be oriented parallel to the first edge B1 of the cell CEL1.

The collection fingers COL can also be oriented perpendicular to the first edge B1. However, in this case and in order to facilitate circulation of the electrical currents collected within the string STR, it is advantageous for at least one collection finger COL to be parallel to the first edge B1 and to be electrically connected to the other collection fingers COL, thus enabling the currents to be concentrated and distributed to connection elements EC1. The latter are preferably perpendicular to the first edge B1.

In the embodiment of FIG. 4, the string STR comprises cells CEL1, CEL2 whose collection fingers COL1, COL2 are oriented differently. According to this example, the collection fingers COL1 of the first cell CEL1 are oriented parallel to the first edge B1 while the collection fingers COL2 of the second cell CEL2 are oriented perpendicular to the first edge B1. The string STR of FIG. 4 can therefore comprise intermediate cells according to prior art, connected in shingles and whose collection finger orientation is of little importance, showing however improved reliability by virtue of the end cell, that is the first cell CEL1, comprising the connection elements EC1 extending to the first connector M1.

The collection fingers COL gather a set of conductive tracks extending over the first face AV and can be made by screen-printing a conductive ink. The conductive ink comprises, for example, a resin loaded with a metal particles. In order not to compromise the integrity of the first cell CEL1, especially when the latter is made from a silicon heterojunction stack, the cross-linking temperature of the conductive ink is preferably less than or equal to 200° C.

In order to improve circulation of the electrical currents collected, the first face AV may also comprise connection conductors CL electrically connecting at least some of the collection fingers together. For this, they connect a first collection finger COL with a second collection finger. Advantageously, the connection conductors CL extend perpendicular to the first edge B1. The connection conductors CL may also be a set of conductive tracks screen-printed on the first face AV.

The second face AR of the first cell CEL1, and advantageously each cell CEL1-4, may also comprise collection fingers, especially when it is to be exposed to incident radiation. If this is not the case, the second face AR may comprise a so-called “full plate” metallisation, that is covering the entire second face AR.

The cells of the string STR are interconnected two by two. This means that they are electrically and mechanically connected to each other, especially to allow circulation of the electrical currents collected. Within the scope of the invention, at least some of the cells in the string and preferably all the cells in the string are interconnected as shingles. This means that one cell partially covers a consecutive cell, with the electrical and mechanical interconnection taking place in the zone covered. The shingled interconnection allows the active surface area of a string to be optimised in relation to its total surface area.

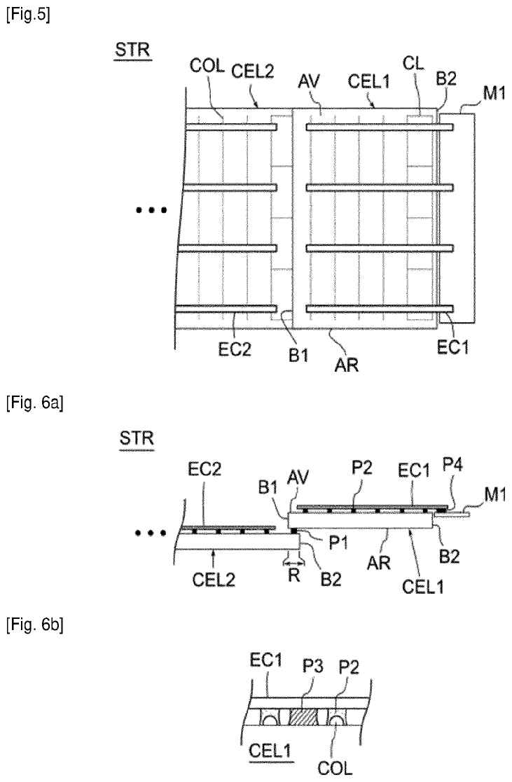

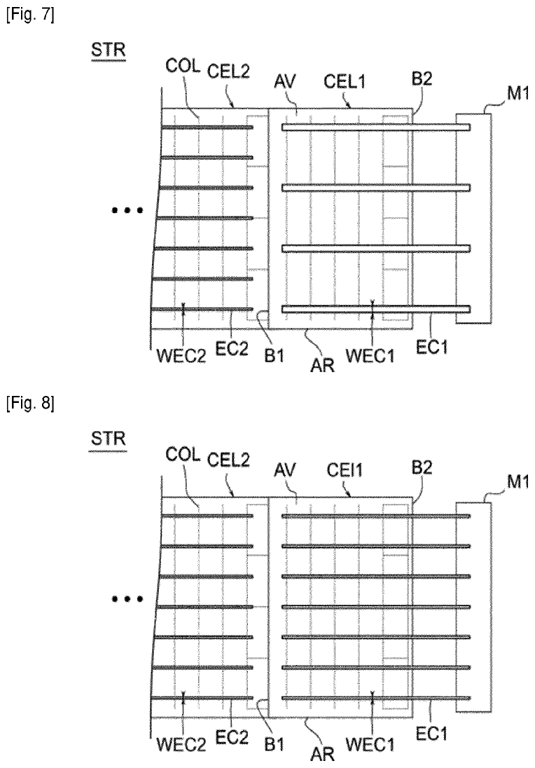

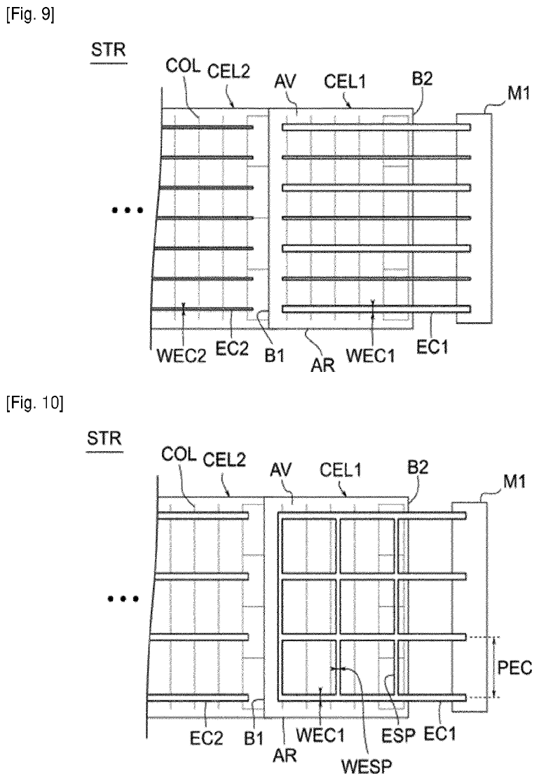

FIG. 6a schematically represents the interconnection of the first cell CEL1 with the second cell CEL2. For this, the first cell CEL1 partially covers the second cell CEL2. The second face AR of the first cell CEL1 thus covers a zone on the first face AV of the second cell CEL2, referred to as the “coverage zone”. For example, the first cell CEL1 covers the second B2 edge of the second cell CEL2. One edge of the first cell CEL1, for example the first edge B1, is vertically above the second cell CEL2. The coverage zone thereby extends between the second edge B2 of the second cell CEL2 and the first edge B1 of the second cell CEL2.

The electrical and mechanical connection between the first and second cells CEL1, CEL2 can be made by welding or bonding. Welding can be carried out by means of a welding paste advantageously deposited onto the metallisations of each cell CEL1, CEL2. The welding paste comprises, for example, a fusible alloy. The alloy may comprise tin and lead and has a melting temperature slightly below 200° C. The alloy may also comprise tin, silver and copper and also have a melting temperature slightly below 200° C. The temperature of the fusible material is preferably slightly below 200° C. By melting the welding paste and then cooling it, the metallisations of the CEL1 and cell CEL2s can be welded together, giving them low electrical resistance and high mechanical rigidity. However, this rigid connection can transmit expansion stresses due to seasonal temperature variations. Expansion stresses may be induced by the relative expansion of a material encapsulating the string STR by said string STR. These stresses may, for example, give rise to a bend in the string STR. The use of a welding paste, comprising for example a tin and bismuth alloy and having a lower melting temperature, for example in the order of 150° C., makes it possible to limit stresses associated with seasonal expansion. However, the tin and bismuth alloy is stiffer and can break when high mechanical stresses are applied.

Bonding made by means of an electrically conductive adhesive is more advantageous because of its ductility, which makes it possible to compensate for the expansion of the cells CEL1, CEL2 and of the encapsulant, if applicable. The electrically conductive adhesive comprises, for example, an epoxy- or acrylate-based resin loaded with metal, for example silver, particles. The resin can be cross-linked at a relatively low temperature, for example slightly below 200° C. when it contains epoxy or between 140° C. and 170° C. when it contains acrylate. The implementation of an electrically conductive adhesive to achieve the interconnection is also of interest when the cells of the string STR are made from silicon heterojunction semiconductor stacks and more particularly when the stack comprises low temperature cross-linked metallisations (discussed previously) and a semiconducting transparent oxide on its surface. Bonding using the electrically conductive adhesive has, on the one hand, sufficient ductility to compensate for expansion stresses and, on the other hand, high adhesion to the transparent conductive oxide located around the metallisations. The level of adhesion is two to three times higher on transparent conductive oxide than on insulating oxide. In addition, the thermal budget required to achieve bonding using the electrically conductive adhesive is compatible with heterojunction stacks, which degrade when they reach temperatures above 200° C. for more than a few seconds. Beyond this, the stack layers degrade rapidly, greatly reducing the energy efficiency of the string STR.

The welding paste or electrically conductive adhesive can be deposited, for example by screen printing, in the form of discrete or continuous first portions P1 onto the first face AV of the second cell CEL2, at the coverage zone R. At least some of the first portions P1 are advantageously electrically connected with the collection fingers of the first face AV of the second cell CEL2. The first cell CEL1 is then pressed against said first portions P1 and the assembly is heat-treated, so as to cross-link the adhesive or melt and then solidify the welding paste. The first portions P1 thus electrically and mechanically connect the second face AR of the first cell CEL1. When the latter also comprises collection fingers, the first portions P1 are advantageously also connected to the collection fingers of said second face AR.

The string STR according to the embodiment of FIG. 2 also comprises a first metal connector M1 and preferably a second metal connector M2. The first and second connectors M1, M2 are to be connected to an electrical system such as another photovoltaic string, a photovoltaic module or an electrical grid. The photovoltaic string STR can be seen as an electrical dipole with the first and second connectors M1, M2 as its terminals. The first and second metal connectors M1, M2 and the photovoltaic cells CEL1-4 are preferably arranged so that the photovoltaic cells CEL1-4 are disposed between the first and second connectors M1, M2, for example forming a line between the two connectors M1, M2.

FIG. 4 to FIG. 6a and FIG. 7 to FIG. 11 schematically represent several embodiments of the string STR, the figures being centred on the first and second cells CEL1, CEL2 as well as the first connector M1. According to these embodiments, the first cell CEL1 is disposed between the second cell CEL2 and the first connector M1. The first and second cells CEL1, CEL2 are interconnected as a shingle. However, the first connector M1 is not shingle connected with the first cell CEL1 and does not cover the first cell CEL1. Electrical and mechanical connection between the first cell CEL1 and the first connector M1 is provided by first connection elements EC1 (described below). One face of the first connector M1 and the first face AV of the first cell CEL1 are coplanar, for example.

According to the embodiments of FIG. 5 and FIG. 6a, the first connector M1 adjoins the second edge B2 of the first cell CEL1, or it may even be in contact with said second edge B2 without, however, masking the first cell CEL1. According to the embodiments of FIG. 7 and FIG. 11, the first connector M1 is distant from the first cell CEL1, for example by at least 1 mm, or even at least 5 mm. The distance between the first cell CEL1 and the first connector M1 is measured, for example, from the second edge B2, perpendicular to this second edge B2. The space between the first cell CEL1 and the first connector M1 allows all the cells CEL1, CEL2 and the first connector M1 to deform without applying mechanical stresses to each other. In particular, this avoids the bimetal effect that can occur between two materials with different coefficients of expansion that are connected directly to each other. This is particularly advantageous for interconnecting thin cells with a thickness of less than 160 μm, for example equal to 100 μm. The space between the first cell CEL1 and the first connector M1 also prevents the first cell CEL1 from being short-circuited.

In common with the embodiments of FIG. 2, FIG. 4 to FIG. 6a and FIG. 7 to FIG. 11, the string STR comprises first connection elements EC1 disposed on the first face AV of the first cell CEL1. The first connection elements EC1 may be metal wires or metal tapes. For example, they are made from copper and may also be coated with a fusible alloy, for example a fusible alloy comprising tin and bismuth. The first connection elements EC1 electrically connect at least some of the collection fingers COL of the first face AV together and preferably all the collection fingers COL together.

By electrically connected collection fingers COL, it is meant that an electric current is capable of circulating from one COL collection finger to another, the electrical conduction offered by the surface of the photovoltaic cell not being taken into account. Indeed, the surface of the cell may comprise a transparent conductive oxide, for example of indium-tin oxide, capable of electrically conducting an electric current but in a much more resistive manner than the conductors EC1. Two first collection fingers COL can thus be electrically connected together by means of connection conductors CL, as described with reference to FIG. 3. A third collection finger COL can be electrically connected to the first two collection fingers COL via a first connection element EC1 even though the connection element EC1 is only connected to the third collection finger COL and to only one of the first two collection fingers COL.

For this, the first connection elements EC1 extend over at least some of the collection fingers COL to be electrically connected and preferably over all the collection fingers COL to be electrically connected. The first connection elements EC1 are not conductive tracks screen-printed on the first face AV. They are preferably separate conductors deposited onto the first face AV and welded or bonded to said first face and more particularly to collection fingers COL. The connection elements EC1 may, for example, be directly welded or bonded to the collection fingers COL to be electrically connected. The connection elements EC1 can be welded to the collection fingers COL by melting a fusible alloy surrounding each first connection element EC1. In this first case, the first connection elements EC1 are pressed against each collection finger COL and heat treated to fuse and solidify the fusible alloy. The connection elements EC1 may also be bonded or welded to the collection fingers COL by means of second portions P2 of electrically conductive adhesive or welding paste, illustrated in FIG. 6a, disposed at the intersection of each first connection element EC1 with a collection finger COL to be electrically connected. In the latter case, the first connection elements EC1 can be pressed against the second portions P2 of adhesive or welding paste, previously deposited onto each collection finger COL, in order to make a mechanical and electrical connection. Adhesion is preferably completed by heat treatment to cross-link the electrically conductive adhesive resin or to melt and then solidify the welding paste. It is also contemplatable to deposit third portions P3 of adhesive or welding paste, as illustrated in FIG. 6b, between each first connection element EC1 and two consecutive collection fingers COL in order to improve mechanical strength of the connection elements EC1 on the first cell CEL1. The third portions P3 of adhesive or welding paste deposited between the collection fingers COL are not necessarily conductive since they play little or no part in conducting the electrical currents collected. The second and/or third portions P2, P3 of adhesive or welding paste are preferably screen-printed on the first face AV of the first cell CEL1. The third portions P3, requiring less precise location, can also be deposited by ink jet, especially when the adhesive P3 is non-conductive.

The first connection elements EC1 may be tapes or wires advantageously having a small width or a diameter of less than 0.3 mm. Expansion of the first connection elements EC1 applies a low or even negligible stress to the collection fingers COL to which they are welded/bonded, thereby not reducing reliability of the string STR.

The first connection elements EC1 advantageously extend perpendicular to the collection fingers COL. When the latter are parallel to the first edge B1, the connection elements EC1 extend perpendicular to the first edge B1. As a reminder, the first edge B1 is advantageously vertically above the second cell CEL2.

Similarly to the first connection elements EC1, the string STR may also comprise second connection elements EC2, for example illustrated in FIG. 6a, disposed on the first face AV of the second cell CEL2. The second connection elements EC2 also electrically connect at least some of the collection fingers COL of the first face AV of the second cell CEL2, or even all the collection fingers COL.

The second connection elements EC2 may also be welded or bonded to the collection fingers COL, for example by melting an alloy surrounding each second connection element EC2 or by means of second portions of electrically conductive adhesive or welding paste, as described previously.

Unlike the second connection elements EC2, the first connection elements EC1 extend beyond the first cell CEL1 up to the first connector M1. In other words, each of the first connection elements EC1 extends over the first face AV and intersects the second edge B2 so as to join the first connector M1. The first connection elements EC1 are connected to the first connector M1 so as to electrically connect at least part of the collection fingers COL of the first face AV with the first connector M1.

As the collection fingers COL are distributed over the first face AV of the first cell CEL1, the first connection elements EC1 advantageously extend from the consecutive collection finger of the first edge B1 to the first connector M1. The first connection elements EC1 thus each comprise an end disposed in the vicinity of the first edge B1, for example within 5 mm of the first edge B1.

When the first connector M1 adjoins the first cell CEL1, as illustrated by FIG. 5 and FIG. 6a, the first connection elements EC1 may extend integrally over at least part of the first cell CEL1 and at least part of the first connector M1. When the first connector M1 is remote from the first cell CEL1, as illustrated in FIG. 7 to FIG. 11, the first connection elements EC1 may be suspended between the first cell CEL1 and the first connector M1. In other words, each first connection element EC1 may comprise a free portion, vertically above neither a photovoltaic cell nor a metal connector.

Electrical connection of the first connection elements EC1 to the first connector M1 can be made by simple contact. In other words, connection between the first connection elements EC1 and the first connector M1 is not rigid and may, on the contrary, be a sliding connection. The first connection elements EC1 may be elastic or include a spring element so as to apply contact pressure to the first connector M1. In this way, the first cell CEL1 and the first connector M1 can deform or move relative to each other without causing any loss of electrical connection or mechanical stress.

Electrical connection of the first connection elements EC1 to the first connector M1 can be made by welding or bonding. In this way, connection between the first connection elements EC1 and the first connector M1 is rigid and ensures a low-resistance and reliable electrical connection, even when significant mechanical stresses are applied between the first cell CEL1 and the first connector M1.

Bonding or welding may be performed by means of fourth portions P4 of electrically conductive adhesive or welding paste, as illustrated in FIG. 6a, in contact with each first connection element EC1 and the first connector M1. The fourth portions P4 of adhesive or welding paste participate in the electrical connection and are therefore preferably conductive. Welding can also be carried out by melting a fusible alloy surrounding either the connection elements EC1 or the first metal connector M1, or surrounding both. In the latter case, the fusible alloys may be of the same composition or of a different composition. The implementation of a fusible alloy is interesting because it is sufficient to heat only the first metal connector instead of the whole string STR to carry out welding. Thus, the thermal budget of each cell CEL1, CEL2 can be reduced.

The current generated by a cell depends, among other things, on the active surface area of the cell, that is the surface area that can be exposed to incident radiation. In other words, this is the surface area not masked by connection elements or collection fingers. In this way, shading induced by the first elements EC1 reduces the active surface area and potentially limits the electric current that can be generated. The shading corresponds to the surface area of the first face AV masked by elements, regardless of whether these are collection fingers COL or first connection elements EC1. The invention makes it possible to reduce effective shading of the first face AV of the first cell compared with a string of prior art. Without taking shading caused by the collection fingers into account, the shading of a connector according to prior art, offset to a distance of 1 mm from a long edge and extending over the entire length of said long edge, may be equal to 156 mm².

By virtue of the invention, the shading of the first face AV of the first cell CEL1 can be reduced. Without considering the collection fingers, the shading of said first face AV is equal to the sum of the products of an offset length and an offset width for each first connection element EC1. The offset length of a first connection element EC1 is measured from the second edge B2 to the end of said first connection element EC1 disposed on the first face AV, which may be adjacent to the first edge B1. The offset width of a first connection element EC1 may be equal to the width WEC1 measured parallel to the second edge B2 of said first connection element EC1.

Each first connection element EC1 may be a metal tape respectively having a width less than or equal to 0.3 mm, for example equal to 0.2 mm, and extending for example over an offset length of 31.2 mm. The width WEC1 of each first connection element EC1 is for example measured parallel to the second edge B2. Thus, the shading of six first connection elements EC1 is less than or equal to 56 mm² and for example equal to 37.5 mm². The shading according to the invention is therefore 60% to 75% less than a string according to prior art.

Shading can be further reduced when the connection elements EC1 are metal wires. This is because metal wires have reduced effective shading due to side reflections. The effective shading of a metal wire is equal to approximately 70% of the diameter of said wire. Thus, the effective shading provided by six first wired connection elements EC1, having a diameter less than or equal to 0.3 mm, for example equal to 0.2 mm, and extending over 31.2 mm, is less than or equal to 39 mm², for example equal to 26 mm². The effective shading according to the invention is therefore 75% to 83% lower than a string according to prior art.

Each first connection element EC1 used in greater number may be a metal wire with a width less than or equal to 0.2 mm, for example equal to 0.15 mm. According to another example, the effective shading of nine first wired connection elements EC1, having a diameter less than or equal to 0.2 mm, for example equal to 0.15 mm, extending over 31.2 mm, is less than or equal to 56 mm², for example 42 mm². The effective shading according to the invention is therefore 64% to 73% lower than a string according to prior art.

In order that the first cell CEL1 only slightly limits the current of the string STR, it is advantageous for the active surface area of the first face AV of the first cell CEL1 to be greater than or equal to the active surface area of the first face AV of the second cell CEL2. Preferably, the active surface area of the first face AV of the first cell CEL1 is greater than or equal to the active surface area of the first face AV of a cell in the string STR with the smallest active surface area. It is therefore advantageous for the shading of the first elements EC1 to be less than or equal to the shading of the second elements EC2 of the second cell CEL2. For example, it is advantageous for the number of first elements EC1 to be less than or equal to the number of second elements EC2 of the second cell CEL2, as illustrated by FIG. 5, FIG. 7 and FIG. 8. In this way, the first face AV of the first cell CEL1 is masked by as many or even fewer elements than the first face AV of the second cell CEL2 and its active surface area is greater than or substantially equal to the active surface area of the first face AV of the second cell CEL2. Substantially equal can be taken to mean equal to within +/−5%, or even less. The first cell CEL1 therefore limits the current in the string STR little or not at all.

The increase in the number of second elements EC2 on the second cell CEL2 makes it possible to reduce width of the collection fingers on this cell. As there are more second connection elements EC2, they are also less widely spaced, thereby reducing the path taken by the electrical currents collected. The electrical current density circulating in the collection fingers COL of the second cell CEL2 is therefore lower. The collection fingers of the second cell CEL2 can therefore be thinner than the collection fingers of the first cell CEL1. The width WEC2 of each second connection element EC2 may also be less than or equal to the width of the first connection elements EC1, as illustrated in FIG. 7 to FIG. 9.

In order to provide sufficient mechanical reliability of the string STR, it is advantageous for the first connection elements EC1 to be wider than the second connection elements EC2. Indeed, the latter do not participate in the mechanical connection within the string and may therefore have a small width or diameter. The first connection elements EC1 can be directly involved in the mechanical connection within the string STR, especially when they are bonded or welded to the first connector M1. It is therefore advisable for at least some of the first connection elements EC1, or even all the first connection elements EC1, to have a width WEC1 greater than or equal to the width WEC2 of each second connection element EC2. This example is especially illustrated by FIG. 7, FIG. 9 and FIG. 11.

For example, however, FIG. 7 illustrates one embodiment in which the width WEC1 of each first connection element EC1 is greater than the width WEC2 of each second connection element EC2. The shading caused by the first connection elements EC1 is compensated for by the number of first elements EC1 being proportionately less than the number of second elements EC2 in the second cell CEL2. As there are more second connection elements EC2, the current density that each element carries is lower. They can therefore be thinner, further reducing the shading caused.

The embodiment of FIG. 9 is particular in that it comprises:
first so-called “wide” connection elements EC1, having a width WEC1 greater than the width WEC2 of the second connection elements EC2; and
first so-called “thin” connection elements EC1, having a width WEC1 less than or equal to the width WEC2 of the second connection elements EC2.

The first thin elements EC1 are preferably framed by first wide elements EC1. By virtue of the thin first elements EC1, the first elements EC1 are more numerous, reducing path of the currents collected in each collection finger. Thus, the width of the collection fingers can be reduced. In this way, the amount of raw material required to make the collection fingers can be reduced and the shading caused by the collection fingers can also be reduced.

The shading caused by the first thin and wide connection elements EC1 can also be compensated for by a first cell CEL1 which is longer than each other cell CEL2 in the string STR. In this way the active surface area is enlarged and the end cell CEL1 is no longer the limiting cell in the string STR.

The manufacture of the string STR can be simplified in that it comprises spacing means ESP configured to ensure constant pitch PEC between the first connection elements EC1. By pitch, it is meant the distribution period of the first connection elements EC1 on the first face AV of the first cell CEL1, preferably parallel to the second edge B2. Thus, the number, width WEC1 and pitch PEC of the first connection elements EC1 can be judiciously dimensioned to ensure low resistivity and high mechanical reliability of the string STR. In the absence of spacing means ESP, a first connection element could be too far away from the other connection elements, increasing the electric current likely to circulate in this first connection element and/or increasing the mechanical stresses likely to be exerted on this first connection element.

For example, the spacing means ESP may comprise a support film. During manufacture of the string STR, the first connection elements EC1, and advantageously the second connection elements EC2, may be integral with the support film. Once the cells CEL1-4 have been interconnected, the support film can be applied to the entire string STR, covering each first face AV of each cell CEL1-4 and at least the first connector M1. The support film thus ensures correct positioning of the connection elements EC1, EC2 on each cell CEL1-4 and on the first connector M1.

However, the implementation of a support film requires specific equipment and may complicate the manufacture of the string STR. Thus, according to another example, the spacing means ESP comprise a plurality of conductive wires, as illustrated in FIG. 10 and FIG. 11. Advantageously, each conductive wire is integral with each first connection element EC1. The conductive wires and the first connection elements EC1 can be made in a single step so as to have an assembly with a mechanical strength that makes it easier to handle, for example by obtaining a copper grid produced by electroplating, possibly a multilayer grid comprised of a copper base and a fusible coating that makes it easier to offset it to the cell by welding. Thus, the conductive wires can participate in the electrical connection between at least some of the collection fingers COL and the first connector M1. However, in order to reduce shading caused by the conductive wires, they are limited in number, for example two or three, preferably parallel to the collection fingers COL and advantageously aligned with at least part of the collection fingers COL. The grid thus formed by the plurality of conductive wires and the first connection elements EC1 facilitates deposition of the first connection elements EC1 at the first cell CEL1 and the first connector M1. The width WESP of the conductive wires, for example measured perpendicularly to the first edge B1, is advantageously less than or equal to the width WEC1 of the first connection elements EC1.

In order to form a dipole which is easily connectable to an electrical grid, the string STR advantageously comprises a third cell CEL3 and a second connector M2, as illustrated in FIG. 2. The string STR advantageously comprises a plurality of third connection elements EC3 configured to electrically connect the second connector M2 and the second face AR of the third cell CEL3. The third connection elements EC3 advantageously extend over the second face AR of the third cell CEL3. In the same way as the first connection elements, the third connection elements EC3 advantageously extend beyond the third cell CEL3, up to the second connector M2. Thus, the second connector M2 can be distant from the third cell CEL3, for limiting the bimetal effect on said third cell CEL3. The string STR is thus more reliable.

When the second face of the third cell CEL3 comprises a plurality of collection fingers, the third connection elements advantageously electrically connect at least some of the collection fingers to the second connector M2, or even all the collection fingers to the second connector M2. When the second face AR of the third cell CEL3 comprises a full plate metallisation, the third connection elements EC3 advantageously electrically connect this metallisation of the second face AR to the second connector M2.

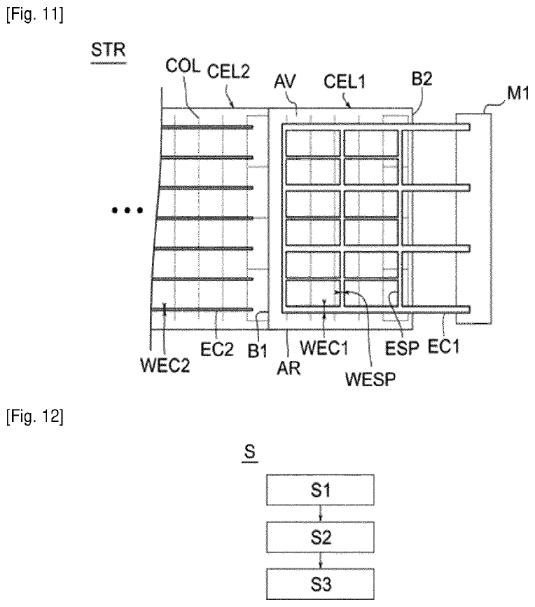

FIG. 12 schematically represents a manufacturing method according to the invention, for manufacturing a string according to the invention.

The method firstly comprises a step of providing S1a first and a second photovoltaic cell and a first metal connector. Of course, the method advantageously comprises providing a second metal connector so as to form a complete string, or even providing additional photovoltaic cells. The photovoltaic cells retain the characteristics of the cells described above. The providing step S1 also comprises arranging the cells so that the first cell is disposed between the second cell and the first connector.

The method S also comprises a step of interconnecting S2 the first cell to the second cell and advantageously all the cells in the string. The cells are interconnected as shingles, the second face of the first cell partially covering the first face of the second cell and so on where appropriate. The method S according to the invention is simplified in that it is not necessary to connect the metal connectors to the interconnected cells in the same step. Thus, the system implementing the interconnection step S2, called a “stringer, is simpler because it does not need to manage and connect elements of different natures in different ways.

Finally, the method S comprises a step of electrically connecting S3 at least part of the collection fingers of the first face of the first photovoltaic cell to the first metal connector. The electrical connection is made by means of first connection elements, said first connection elements being disposed on the first face of the first photovoltaic cell, extending beyond the first photovoltaic cell to the first metal connector.

1. A photovoltaic string comprising:
a first photovoltaic cell;
a second photovoltaic cell;
a first metal connector, the first photovoltaic cell being disposed between the second photovoltaic cell and the first metal connector, each of the first and second photovoltaic cells comprising a first face and a second face opposite to the first face, said first faces each comprising a plurality of collection fingers extending parallel to each other, the first photovoltaic cell being interconnected to the second photovoltaic cell, the second face of the first photovoltaic cell partially covering the first face of the second photovoltaic cell, and
a plurality of first connection elements, said first connection elements being disposed on the first face of the first photovoltaic cell and extending beyond the first photovoltaic cell, up to the first metal connector, and wherein the first connection elements electrically connect at least part of the collection fingers of the first face of the first photovoltaic cell to the first metal connector.

2. The photovoltaic string according to claim 1, wherein the first metal connector is distant from the first photovoltaic cell.

3. The photovoltaic string according to claim 2, wherein the first photovoltaic cell comprises a first edge vertically above the first face of the second photovoltaic cell and wherein the collection fingers extend parallel to the first edge and wherein each connection element extends perpendicular to the collection fingers.

4. The photovoltaic string according to claim 3, wherein each first connection element comprises an end disposed within 5 mm of the first edge.

5. The photovoltaic string according to claim 1, comprising a second plurality of connection elements, the second connection elements electrically connecting at least some of the collection fingers of the first face of the second photovoltaic cell to one another, a number of second connection elements being greater than or equal to a number of first connection elements.

6. The photovoltaic string according to claim 5, wherein a width of each first connection element is greater than or equal to a width of each second connection element.

7. The photovoltaic string according to claim 1, comprising spacing means configured to ensure constant pitch between the first connection elements.

8. The photovoltaic string according to claim 7, wherein the spacing means comprise a plurality of conductive wires and wherein each conductive wire is integral with the first connection elements and extends perpendicular to the first connection elements so that the plurality of conductive wires and the first connection elements form a grid.

9. The photovoltaic string according to claim 1, wherein the spacing means comprise a support film integral with the first connection elements.

10. The photovoltaic string according to claim 1, comprising:
a third photovoltaic cell, and
a second metal connector,
the third photovoltaic cell being disposed between the second photovoltaic cell and the second metal connector, the third photovoltaic cell comprising a first face and a second face opposite to the first face, a plurality of third connection elements electrically connecting the second metal connector to the second face of the third photovoltaic cell.

11. The photovoltaic string according to claim 2, wherein the first metal connector is distant from the first photovoltaic cell by at least 1 mm.
